(19) United States
(12) Patent Application Publication
(10) Pub. No.: US 2026/0130179 A1
(43) Pub. Date: May 7, 2026

(54) ELECTRONIC CHIP COMPRISING A CRACK DETECTION DEVICE

(71) Applicant: STMicroelectronics International N.V., Geneva (CH)

(72) Inventor: Gregoire JOUAN, Voiron (FR)

(73) Assignee: STMicroelectronics International N.V., Geneva (CH)

(21) Appl. No.: 19/380,383

(22) Filed: Nov. 5, 2025

(30) Foreign Application Priority Data
Nov. 6, 2024 (FR) FR2412129

(51) Int. Cl. H01L 21/66; H01L 23/00; H01L 23/58

(52) U.S. Cl. CPC H10P 74/273; H10W 42/00; H10W 42/121

(57) ABSTRACT

An electronic chip includes a crack detection device formed inside and on top of a substrate or on top of the substrate. The device includes a conductive path made of an alternation of lower and upper conductive strips, where each lower strip includes first and second conductive vias in contact with the lower strip, third and fourth conductive vias in contact with respectively an upper strip and another upper strip, and first and second conductive tracks respectively connecting the first and third vias and the second and fourth vias. The first and second vias are located vertically in line respectively with a first end and a second end of the lower strip, and the third and fourth vias are located vertically in line respectively with one end of the upper strip and of the other upper strip.

### PRIORITY CLAIM

This application claims the priority benefit of French Application for Patent No. FR2412129, filed on November 6, 2024, the content of which is hereby incorporated by reference in its entirety to the maximum extent allowable by law.

### TECHNICAL FIELD

The present disclosure generally concerns electronic chips or integrated circuits and, in particular, an electronic chip comprising a crack detection device, for example integrated in a seal ring.

### BACKGROUND

In industry, most electronic devices are manufactured in series. A plurality of electronic chips are thus usually manufactured inside and on top of a same semiconductor substrate, for example a same semiconductor wafer. The electronic chips can then be separated, or individualized or singulated, to be able to be used, for example, alone or in an electronic device comprising other components. This individualization is usually performed by cutting, for example by means of a saw.

During this individualization, for example during the cutting of a semiconductor wafer, a crack may form at one edge of a chip and propagate into the chip. Such a crack may lead to a failure of the electronic circuits of the electronic chip.

Further, cracks may form during the lifetime of the chip, in particular at one edge of the chip, for example due to temperature changes of the electronic chip.

To protect an electronic chip, in particular during the manufacturing, the individualization, or during its use, the electronic chip may include a seal ring at its periphery. A purpose of the seal ring is to prevent the propagation of cracks from the edge to a region of electronic circuits of the chip. A purpose of the seal ring also is to prevent the penetration of moisture into the active regions of the chip. However, the seal ring does not always prevent the forming and the propagation of cracks in the electronic chip. Thus, a chip may comprise a crack detection device, for example incorporated in a seal ring. The crack detection device can be used to test the integrity of the chip upon manufacturing, for example after the cutting step, or during the use of the chip.

It would be desirable to be able to improve, at least partly, electronic chips, and in particular crack detection devices incorporated in electronic chips.

### SUMMARY

In an embodiment, an electronic chip comprises: a semiconductor substrate and a crack detection device formed inside and on top of the semiconductor substrate or on the semiconductor substrate, the crack detection device comprising, between first and second electrical connection terminals of the device, a serpentine conductive path comprising an alternation of lower conductive strips and of upper conductive strips connected in series, wherein the conductive path comprises, for each lower conductive strip: a first conductive via on top of and in contact with the lower conductive strip, a second conductive via on top of and in contact with the lower conductive strip, a third conductive via under and in contact with an overlying upper conductive strip, a fourth conductive via under and in contact with another overlying upper conductive strip, at least one first intermediate conductive track connecting the first and third conductive vias, and at least one second intermediate conductive track connecting the second and fourth conductive vias, the first conductive via being located vertically in line with a first end of the lower conductive strip and the second conductive via being located vertically in line with a second end of the lower conductive strip, the third conductive via being located vertically in line with an end of the overlying upper conductive strip, and the fourth conductive via being located vertically in line with an end of the other overlying upper conductive strip, at least 80% of the length of the crack detection device being occupied, in top view, by the upper conductive strips and at least 80% of the length of the crack detection device being occupied, in bottom, by the lower conductive strips, and wherein the lower conductive strips are made of a doped semiconductor material and the upper conductive strips are made of metal.

According to an embodiment, in the crack detection device: the first conductive via is located vertically in line with a central portion of the overlying upper conductive strip; the second conductive via is located vertically in line with a central portion of the other overlying upper conductive strip; the third conductive via is located vertically in line with a central portion of the lower conductive strip; and the fourth conductive via is located vertically in line said central portion of the lower conductive strip.

According to an embodiment, in the crack detection device, the fourth conductive via is aligned with the second conductive via, the fourth conductive via being located vertically in line with said second end of the lower conductive layer and the second conductive via being located vertically in line with said end of the other overlying upper conductive strip.

According to an embodiment, in the detection device, the third conductive via is located vertically in line with an intermediate portion of the lower conductive strip located in the vicinity of the second end of the lower conductive strip, said intermediate portion being located between the central portion and the second end of the lower conductive strip.

According to an embodiment, for each lower conductive strip, the first via is entirely located vertically in line with the 25%, for example the 20%, of the strip length most distant from the second end of said lower conductive strip, and the second via is entirely located vertically in line with the 25%, for example the 20%, for example, the 10%, of the length of the lower conductive strip most distant from the first end of said lower conductive strip.

According to an embodiment, for each lower conductive strip, said central portion of the lower conductive strip occupies less than 50%, preferably less than 30%, and more preferably less than 20%, of the length of said lower conductive strip.

According to an embodiment, the lower conductive strip is made of silicon.

According to an embodiment, the chip is delimited by an edge and the crack detection device is arranged between the edge of the electronic chip and a region of electronic circuits of the electronic chip.

According to an embodiment, the semiconductor substrate comprises a doped portion of a first conductivity type, the lower conductive strip being entirely formed in the portion of the semiconductor substrate.

According to an embodiment, the lower conductive strips are separated two by two by insulating trenches.

According to an embodiment, the third conductive via and the fourth conductive via connected to a same upper conductive strip are associated with two consecutive lower conductive strips, the third conductive via being associated with one lower conductive strip and the fourth conductive via being associated with another lower conductive strip.

According to an embodiment, the lower conductive strip is separated from the other lower conductive strip by a distance in the range from 5 nm to 10 µm.

According to an embodiment, the upper conductive strip is separated from the other upper conductive strip by a distance in the range from 20 nm to 10 µm.

According to an embodiment, the crack detection device comprises a plurality of sections, each section comprising a first and a second electrical connection terminals of the device.

Another embodiment provides a method of manufacturing an electronic chip, comprising a step of forming a crack detection device inside and on top of a semiconductor substrate or on top of the semiconductor substrate, the crack detection device comprising, between first and second electrical connection terminals of the device, a serpentine conductive path comprising an alternation of lower conductive strips and of upper conductive strips connected in series, wherein the conductive path comprises, for each lower conductive strip: a first conductive via on top of and in contact with the lower conductive strip, a second conductive via on top of and in contact with the lower conductive strip, a third conductive via under and in contact with an overlying upper conductive strip, a fourth conductive via under and in contact with another overlying upper conductive strip, at least one first intermediate conductive track connecting the first and third conductive vias, and at least one second intermediate conductive track connecting the second and fourth conductive vias, the first conductive via being located vertically in line with a first end of the lower conductive strip, the second conductive via being located vertically in line with a second end of the lower conductive strip, the third conductive via being located vertically in line with an end of the overlying upper conductive strip, and the fourth conductive via being located vertically in line with one end of the other overlying upper conductive strip, the length of the crack detection device being occupied, in top view, at 80% by the upper conductive strips and, in bottom view, at 80% by the lower conductive strips, and wherein the lower conductive strips are made of a doped semiconductor material and the upper conductive strips are made of metal.

According to an embodiment, the method comprises a step of testing the electrical conductivity between the first terminal of the crack detection device and the second terminal of the crack detection device, so as to detect a possible crack cutting the conductive path.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIGS. 1A to 1C are views, partial and simplified, of an example of an electronic chip;

FIGS. 2A and 2B are views, partial and simplified, of an example of an electronic chip according to an embodiment; and

FIG. 3 is a cross-section view, partial and simplified, of an example of an electronic chip according to another embodiment.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, not all the manufacturing steps and all the details of the electronic chips are described, the described embodiments being compatible with usual electronic chip manufacturing methods. In particular, the electronic circuits of the electronic chips are not detailed, the embodiments being compatible with different electronic circuits in an electronic chip. Further, not all the manufacturing steps and all the details of the seal rings and crack detectors are described, the described embodiments being achievable with usual seal ring and crack detector manufacturing methods.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms "front", "back", "top", "bottom", "left", "right", etc., or relative position qualifiers, such as the terms "top", "bottom", "upper", "lower", etc., or orientation qualifiers, such as "horizontal", "vertical", etc., reference is made unless otherwise specified to the orientation of the drawings.

Unless specified otherwise, the expressions "about", "approximately", "substantially", and "in the order of" signify plus or minus 10% or 10°, preferably of plus or minus 5% or 5°.

In the following description, the terms "insulating" and "conductive" respectively signify, unless otherwise specified, electrically insulating and electrically conductive. Similarly, the term "insulate" means, unless otherwise specified, electrically insulate.

In the following description, unless otherwise specified, when reference is made to a chip, reference is made to an electronic chip, when reference is made to a via, reference is made to a conductive via. Further, in the following description, the term via does not necessarily refer to a unit element but may, for example, be formed of a plurality of elements enabling to ensure the electrical connection function.

In the following description, when reference is made to a crack detection device, or in short to a crack detector, reference is made to a device capable of detecting a structural defect which is not limited to a crack, for example it may be a breach or a delamination. For the sake of brevity, when reference is made to a crack, this can include a breach, a delamination, or any other similar structural defect.

In the following description, a first metallization level of an interconnection structure generally corresponds to a metallization level closest to a semiconductor substrate having the interconnection structure formed thereon and having the interconnection structure connected thereto. A second metallization level of the interconnection structure corresponds to a metallization level more distant from the semiconductor substrate than the first metallization level. More generally, a metallization level N+1 corresponds to a metallization level more distant from the semiconductor substrate than metallization level N.

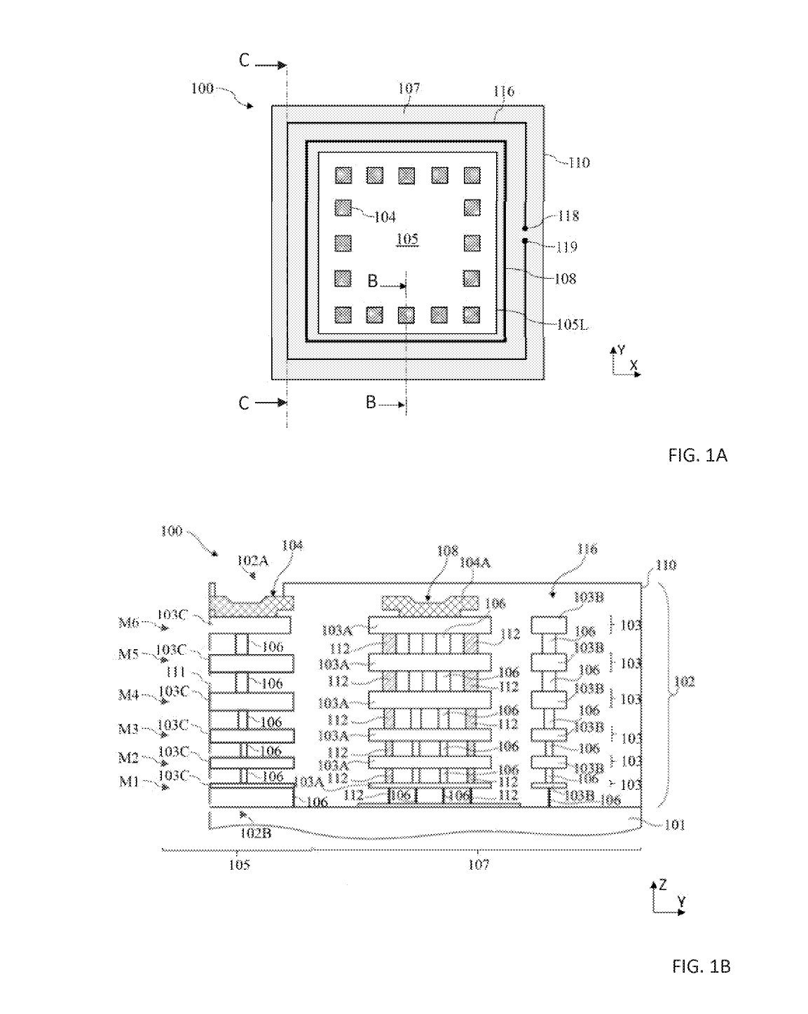

FIGS. 1A to 1C are views, partial and simplified, of an example of an electronic chip 100. In particular, FIG. 1A is a top view, FIG. 1B is a cross-section view along the cross- section plane BB of FIG. 1A and FIG. 1C is a cross-section view along the cross-section plane CC of FIG. 1A.

In FIGS. 1A to 1C, electronic chip 100 is shown as already individualized. However, in practice, the present disclosure can also apply to a non-individualized chip, when the chip is still part of a semiconductor wafer comprising, for example, a plurality of chips.

Chip 100 comprises a semiconductor substrate 101, for example made of silicon, for example, made of single-crystal silicon. Chip 100 comprises, for example, electronic circuits formed on top and inside of substrate 101. The electronic circuits are, in top view, formed in a region of electronic circuits 105, or circuit region, of chip 100. As an example, in top view, circuit region 105 is located in a central portion of chip 100. Region 105 is, for example, delimited by a circumference 105L. As an example, circuit region 105 comprises all the electronic circuits of chip 100.

As an example, the circuit region 105 of chip 100 is laterally surrounded by a sealing structure 107 or seal ring. In other words, sealing structure 107 is formed at the periphery of chip 100, that is, between circuit region 105 and an edge 110 of chip 100. Sealing structure 107 has, for example, a ring shape in top view. As an example, chip 100 comprises electrical connections between circuit region 105 and sealing structure 107.

In this example, sealing structure 107 is formed in an interconnection structure 102 arranged above semiconductor substrate 101, for example in contact with semiconductor substrate 101. This interconnection structure 102 is also designated with the expression "back end of line interconnection structure", or "BEOL" interconnection structure for short. Interconnection structure 102 may comprise, for example in a central portion of the chip, metal elements for interconnecting the electronic circuits of the chip.

Sealing structure 107 is arranged in interconnection structure 102, at the periphery of chip 100.

Interconnection structure 102 comprises, for example, a plurality of metallization levels. In FIGS. 1B and 1C, six metallization levels M1, M2, M3, M4, M5, M6 have been shown. In practice, the number of metallization levels may be different from six.

As an example, within circuit region 105, the metallization levels each comprise at least one portion 103C of a conductive layer 103. As an example, each portion 103C corresponds to a conductive element in the form of a conductive track, or conductive line.

Conductive layer 103 is, for example, a metal layer, for example made of copper.

The portions 103C of the different metallization levels are, for example, electrically connected to each other by conductive vias 106. As an example, the upper metallization level, for example, metallization level M6, is connected by its upper surface to a connection pad 104. As an example, pads 104 are arranged on an upper surface 102A of interconnection structure 102, a lower surface 102B of the interconnection structure, opposite to upper surface 102A, being in contact with semiconductor substrate 101.

Pads 104 are, for example, distributed in a substantially ring-shaped manner, in this case a square-shaped ring, in the circuit region 105 of chip 100. The described embodiments are however not limited to this specific arrangement.

Pads 104 are configured to be in contact with conductive elements located outside chip 100, so as to electrically connect the chip to an external system.

The metallization levels of interconnection structure 102 are, for example, surrounded by insulating layers, which are all designated by one and the same reference 111.

A targeted function of sealing structure 107 is to prevent the propagation of cracks from the edge 110 of chip 100 to the circuit region 105 of chip 100.

Another targeted function of sealing structure 107 may be to block the propagation of moisture from the outside of chip 100, that is, from the edge 110 of chip 100, to the electronic circuits of the circuit region 105 of chip 100.

To fulfil one or a plurality of these functions, sealing structure 107 may include one or a plurality of sealing elements 108, each sealing element 108 having an ring shape in top view.

Each sealing element 108 extends in height from semiconductor substrate 101 through all or part of the metallization levels M1-M6 of interconnection structure 102, for example through one or a plurality of lower metallization levels of interconnection structure 102. For protection against moisture, it is however preferable for sealing element 108 to extend all the way to the upper metallization level, here level M6.

The shown sealing element 108 forms a closed loop around the circuit region 105 of chip 100, or, in other words, sealing element 108 completely surrounds the circuit region 105 of chip 100.

In the embodiment shown in FIG. 1B, sealing element 108 forms a ring-shaped wall comprising other portions 103A of the conductive layers 103 of interconnection structure 102. More specifically, sealing element 108 comprises a portion 103A of the conductive layer 103 of each metallization level M1-M6 of interconnection structure 102. Each portion 103A of conductive layer 103 forms a ring-shaped conductive plate at each metallization level. The successive ring-shaped conductive plates 103A of sealing element 108 are interconnected by one or a plurality of ring-shaped conductive strips 112, which extend continuously between two successive ring-shaped conductive plates 103A.

As shown in FIG. 1B, the successive ring-shaped conductive plates 103A of sealing element 108 may further be coupled to each other by conductive vias 106 of interconnection structure 102, for example enabling to increase the mechanical resistance of sealing element 108 to a crack propagation.

Sealing element 108 may form a protective wall against the propagation of moisture to the circuit region 105 of chip 100.

As shown in FIG. 1B, sealing element 108 may comprise a dummy pad 104A, which is, for example, formed at the same time as pads 104. Dummy pad 104A rests on the ring-shaped conductive plate 103A at the upper metallization level M6 of interconnection structure 102. Dummy pad 104A may be arranged in substantially ring-shaped fashion, here it forms a square-shaped ring. There may be a plurality of dummy pads.

In order to detect cracks in chip 100, sealing structure 107 may include a crack detection device 116, or crack detector. In this example, crack detector 116 is formed on semiconductor substrate, in interconnection structure 102. As shown in FIGS. 1A, 1B, and 1C, crack detection device 116 may be arranged in a region between the edge 110 of chip 100 and sealing element 108. Thus, if a crack appears at the edge 110 of chip 100 and propagates towards circuit region 105, the crack can be detected by crack detection device 116 before sealing element 108. Other configurations can however also be envisaged.

As an example, crack detection device 116 is placed between two separate sealing elements 108. Crack detection devices 116 and sealing elements 108 are not limited to those described. Further, the number of crack detection devices 116 and of sealing elements 108 is not limited. A plurality of copies of crack detection devices 116 and of sealing elements 108 may thus be provided in sealing structure 107.

Crack detection device 116 corresponds to a conductive structure which forms a conductive path, preferably an open loop, between a first terminal, or node 118, for example a first end of detection device 116, and a second terminal 119, for example a second end of detection device 116. By testing the electrical conductivity between the first terminal 118 of detection device 116, and the second terminal 119 of detection device 116, cracks can be detected by detection device 116. As a variant, crack detection device 116 comprises a plurality of sections not electrically coupled together, each section comprising two terminals.

In the example of embodiment shown in FIGS. 1B and 1C, crack detection device 116 comprises a plurality of metal stacks 109, each comprising other portions 103B of conductive layers 103 coupled by conductive vias 106 of interconnection structure 102. Metal stacks 109 are, for example, organized along the length of crack detection device 116. More precisely, each metal stack 109 extends in height in the Z direction perpendicular to the XY plane of semiconductor substrate 101 through all or part of the metallization levels M1-M6 of interconnection structure 102, in the shown example up to upper metallization level M6. As an example, metal stacks 109 each comprise two opposite, for example, identical, vertical portions, coupled together only by the upper metallization level, for example, level M6. Metal stacks 109 thus each have the shape of a bridge having its feet or pillars which are the two vertical portions, and having its deck which corresponds to the conductive layer 103 of metallization level M6.

In the shown example, the adjacent legs of two adjacent metal stacks 109 are only coupled by a metal layer 114 formed in metallization level M1. Thus, crack detection device 116 has, in cross-section view, along the cross-section plane of FIG. 1C, a crenellated serpentine shape having its vertical portions corresponding to the vertical pillars of metal stacks 109 and having its horizontal portions which are, in alternation, portions of the lower layer 114 of lower metallization level M1 and portions of the layer 103 of upper metallization level M6.

It has been observed by the inventors that cracks can propagate in sealing structure 107, or even cross the sealing structure, without being detected by crack detector 116.

In particular, certain vertical cracks are likely to propagate through crack detection device 116, possibly deforming lower metal layer 114 but without breaking it, due to the ductile nature of layer 114. These cracks thus do not cause a break of the conductive path between the terminals 118 and 119 of detection device 116, and are accordingly not detected.

Further, horizontal cracks propagating beneath sealing structure 107, and in particular between layer 114 and substrate 101, may also no be detected.

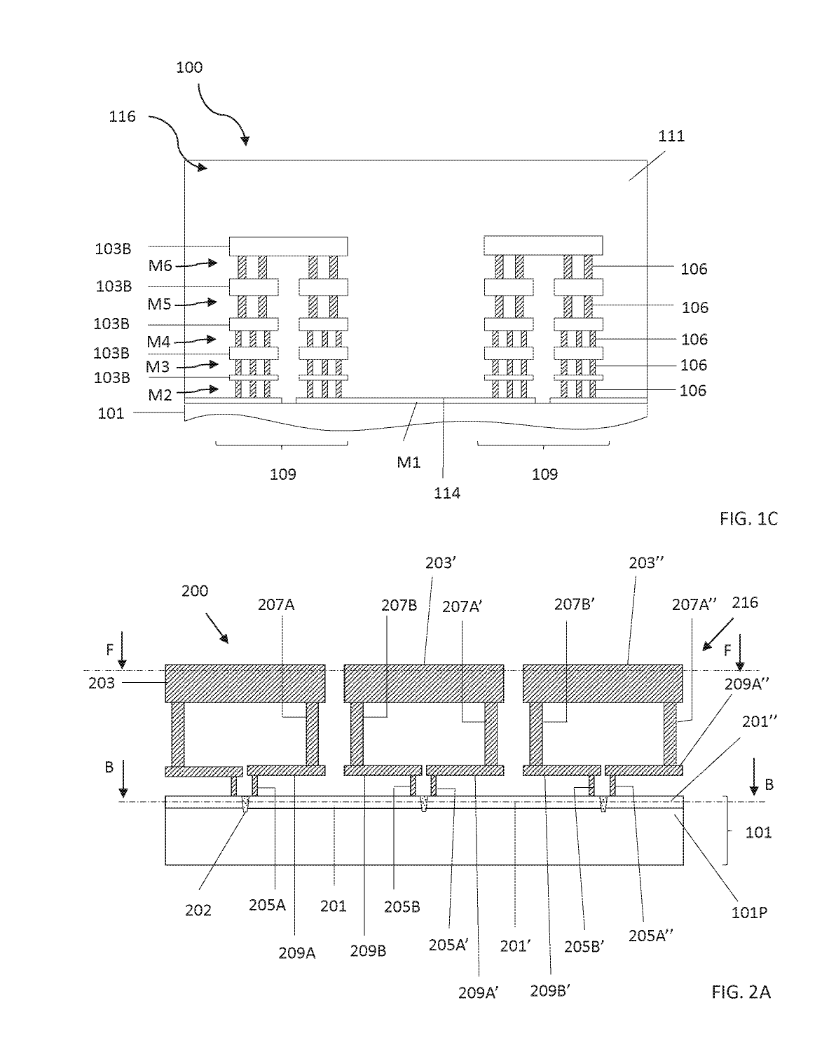

FIGS. 2A and 2B are views, partial and simplified, of an example of an electronic chip 200 according to an embodiment: FIG. 2B being an illustrative photograph in top view and FIG. 2A being a simplified cross-section view along the cross-section plane AA of FIG. 2B.

Electronic chip 200 is, for example, similar to the electronic chip 100 illustrated in FIGS. 1A to 1C, with the difference that chip 200 comprises a crack detection device 216 different from crack detection device 116.

Like the device 116 of FIGS. 1A to 1C, device 216 comprises an electrically-conductive path, for example in the form of an open loop laterally surrounding the active portions of the chip, between two connection terminals (not visible in FIGS. 2A and 2B) corresponding, for example, to terminals 118 and 119 of device 116. In top view, the arrangement of crack detection device 216 is, for example, similar to that of device 116. Similar to what has been described in relation with FIGS. 1A to 1C, crack detection device 216 may comprise a plurality of sections connected by additional terminals. Thus, the number of terminals within crack detection device 216 is not limited to two.

The detection device of FIGS. 2A and 2B comprises a serpentine conductive path comprising an alternation of lower conductive strips 201 and of upper conductive strips 203 connected in series between the connection terminals of the device.

According to an aspect of the described embodiments, the lower conductive strips are made of a doped semiconductor material, for example made of doped silicon.

According to an embodiment, each lower conductive strip 201 is formed by a doped region of substrate 101, so that strips 201 are flush, by their upper surface, with the upper surface of substrate 101. As an example, strips 201 extend in substrate 101 down to a depth in the range from a few nm, for example 10 nm, to 100 nm.

As a variant, conductive strips 201 are buried in substrate 101. In this variant, each conductive strip 201 is extended, all the way to the upper surface of substrate 101, at least on its two ends, for example on its two ends only. As an example, the extension of strips 201 is formed by another conductive layer. Thus, conductive layer 201 does not emerge onto the upper surface of substrate 101, and only the extensions of the other conductive layer emerge onto the upper surface of substrate 101.

As an example, substrate 101 comprises a doped portion 101P of a first conductivity type, for example type P.

As an example, the first portion 101P of substrate 101 extends deeper than conductive strips 201. That is, conductive strips 201 are entirely formed in the upper portion 101P of substrate 101.

The lower conductive strips 201 are, for example, doped with a second conductivity type opposite to that of region 101P. As an example, the lower conductive strips 201 are N-type doped.

This configuration enables to ensure the electrical insulation of strips 201 from each other and from the substrate.

As an example, conductive strips 201 are made of a semiconductor material. As an example, conductive strips 201 are made of a non-ductile material (that is, a material that cannot be elongated, stretched, or extended without breaking), for example less ductile than the metals of the interconnection structure.

As a variant, the lower conductive strips 201 are formed on substrate 101, for example in a level of forming of doped polysilicon conductive gates. More generally, the lower conductive strips 201 may be formed in any other forming level present below metallization level M1.

Conductive strips 201 are, for example, aligned along a longitudinal axis of the conductive path of the crack detector, and not directly connected together. As an example, the conductive strips 201 are separated two by two by insulating trenches 202 made of an insulating material, for example made of silicon oxide. As an example, the trenches 202 extend deeper than the conductive strips 201. Trenches 202 are formed, for example, at the same time as other insulating trenches formed, for example, around transistors in circuit region 105. Trenches 202 are, for example, STI (Shallow Trench Isolation) trenches. As a variant, trenches 202 are, for example, trenches of DTI (Deep Trench Isolation) type.

As an example, the distance between two adjacent strips 201 is greater than 5 nm. The distance between two neighboring strips 201 is, for example, shorter than 10 µm. The distance between two neighboring strips 201 is, for example, shorter than 5 µm. Indeed, the reliability of crack detection device 216 relies among other things on the distance between two adjacent bands 201, this distance thus must be as short as possible in order to increase the reliability of the device.

The upper conductive strips 203 are, for example, aligned along a longitudinal axis of the conductive path of the crack detector, parallel to the lower conductive strips 201, and not directly connected to each other. They are, for example, spaced two by two by a thin region made of a dielectric material of the interconnection structure.

As an example, the distance between two neighboring strips 203 is greater than 20 nm. The distance between two neighboring strips 203 is, for example, shorter than 10 µm. The distance between two neighboring strips 203 is, for example, shorter than 5 µm. Indeed, similarly to what has been described for the distance between strips 201, the reliability of crack detection device 216 relies among other things on the distance between two neighboring strips 203, this distance must thus be as short as possible in order to increase the reliability of the device.

As an example, the lower conductive strips 201 are predominantly covered by the upper conductive strips 203. That is, a majority of the surface area of the lower conductive strips 201 is covered by the upper conductive strips 203.

As an example, the lower strips 201 are formed below and opposite the upper strips 203. The lower strips 201 are however offset from the upper strips 203 so that a central portion of an upper strip 203 is vertically aligned with a separation region between two consecutive lower strips 201, and a central portion of a lower strip 201 is vertically aligned with a separation region between two consecutive upper strips 203. The lower conductive strips 201 and the upper conductive strips 203 have, for example, substantially the same length. As a variant, the lower conductive strips 201 and the upper conductive strips 203 have different lengths.

Each of the lower conductive strips 201 is connected to a first conductive via 205A, each of the first vias 205A being formed on top of and in contact with the conductive strip 201 to which it is connected.

Each first conductive via 205A is located vertically in line with a first end of the lower conductive strip 201 to which it is connected. As an example, each first via 205A is thus entirely vertically in line with the 25%, for example the 20%, for example the 10%, of the length of lower conductive strip 201 most distant from a second end of lower conductive strip 201, opposite to the first end. Further, each first via 205A is, in the embodiment illustrated in FIG. 2A, located vertically in line with a central portion of the overlying upper conductive strip 203.

Each of the lower conductive strips 201 is further connected to a second conductive via 205B, each of the second vias 205B being formed on top of and in contact with the conductive strip 201 to which it is connected.

Each second conductive via 205B is located vertically in line with the second end of the lower conductive strip 201 to which it is connected. As an example, each second via 205B is thus entirely located vertically in line with the 25%, for example the 20%, for example the 10%, of the length of the lower conductive strip 201 most distant from the first end of said lower conductive strip 201. Further, each second via 205B is, in the embodiment illustrated in FIG. 2A, located vertically in line with a central portion of the overlying upper conductive strip 203.

As an example, the vias 205A and 205B associated with the same lower conductive strip 201 are covered by two consecutive upper conductive strips 203. In the example of FIG. 2A, via 205A is covered by upper strip 203 and is formed opposite a central portion of upper strip 203. In the example of FIG. 2A, via 205B is covered by upper strip 203' and is formed opposite a central portion of upper strip 203'.

As an example, the central portion of an upper conductive strip 203, vertically in line with which a first 205A and a second 205B vias are located, occupies less than 50%, preferably less than 30%, and more preferably less than 20%, of the length of said upper conductive strip 203.

Crack detection device 216 further comprises, opposite each conductive strip 201, a third conductive via 207A. The third via 207A is formed under and in contact with an overlying upper conductive strip 203.

Each third conductive via 207A is located vertically above a first end of the upper conductive strip 203 to which it is connected. As an example, each third via 207A is thus entirely located vertically in line with the 25%, for example the 20%, for example the 10%, of the length of the upper conductive strip most distant from a second end of said upper conductive strip 203, opposite the first end. Further, each third via 207A is, in the embodiment illustrated in FIG. 2A, located vertically in line with a central portion of the underlying lower conductive strip 201.

Crack detection device 216 further comprises, opposite each conductive strip 201, a fourth conductive via 207B. The fourth via 207B is formed under and in contact with an overlying upper conductive strip 203.

Vias 207A and 207B are formed under two consecutive upper conductive strips 203. In the example of FIG. 2A, via 207A is formed under upper strip 203. In the example of FIG. 2A, via 207B is formed under upper strip 203'.

Each fourth conductive via 207B is located vertically in line with a first end of the overlying upper conductive strip 203'. As an example, each fourth via 207B is thus entirely located vertically in line with the 25%, for example the 20%, for example th 10%, of the length of the upper conductive strip most distant from a second end of said upper conductive strip 203, opposite to the first end. Further, each fourth via 207B is, in the embodiment illustrated in FIG. 2A, located vertically in line with a central portion of the underlying lower conductive strip 201.

As an example, the central portion of lower conductive strip 201, vertically in line with which the third 207A and fourth 207B vias are located, occupies less than 50%, preferably less than 30%, and more preferably less than 20% of the length of said lower conductive strip 201.

As an example, each upper conductive strip, for example strip 203' in FIG. 2A, is connected: to a fourth conductive via, for example via 207B in FIG. 2A, and to a third conductive via, for example, via 207A' in FIG. 2A, the third and fourth conductive via being formed opposite two consecutive lower strips.

Crack detection device 216 further comprises, vertically in line with each lower strip 201, at least one first intermediate conductive track 209A connecting the first 205A and third 207A conductive vias, and at least one second intermediate conductive track 209B connecting the second 205B and fourth 207B conductive vias.

As an example, the first conductive via 205A is connected to the first intermediate conductive track 209A vertically in line with a first end of the first track 209A. As an example, the third via 207A is connected to the first intermediate conductive track 209A vertically in line with a second end of the first track 209A, opposite to the first end of the first track 209A.

Similarly, as an example, the second conductive via 205B is connected to the second intermediate conductive track 209B vertically in line with a first end of the second track 209B. As an example, the fourth via 207B is connected to the second intermediate conductive track 209B vertically in line with a second end of the second track 209B, opposite to the first end of the second track 209B.

As an example, the serpentine conductive path of crack detection device 216 comprises the succession of upper conductive strips 203, 203', 203'', of third conductive vias 207A, 207A', 207A'', of first intermediate conductive tracks 209A, 209A', 209A'', of first conductive vias 205A, 205A', 205A'', of lower conductive strips 201, 201', 201'', of second conductive vias 205B, 205B', of second intermediate conductive tracks 209B, 209B', and of fourth conductive vias 207B, 207B'.

The upper conductive strips 203 are made of metal or of a metal alloy. As an example, strips 203 are made of copper, aluminum, or an alloy copper and aluminum.

The third 207A and fourth 207B conductive vias are, for example, made of metal, for example made of copper, aluminum, or a mixture of copper and aluminum.

The first 205A and second 205B conductive vias are, for example, made of a metallic material, for example made of tungsten or tantalum, or a mixture of copper and tantalum.

As an example, although this is not shown in FIG. 2A, conductive vias 207A and 207B may each correspond to a conductive stack formed of other conductive intermediate tracks and of vias coupling the intermediate tracks.

In this example, the conductive vias formed between intermediate conductive tracks are formed vertically in line with one of the ends of overlying and underlying conductive tracks, or opposite a central portion of these intermediate conductive tracks.

As an example, the vias coupling two intermediate conductive tracks are vertically aligned.

As a variant, the vias coupling two intermediate conductive tracks are not vertically aligned.

As shown in FIG. 2B, sealing structure 107 may comprise an internal crack detection device 216I arranged in interconnection structure 102 around, or at the edges of, circuit region 105 and surrounded by sealing element 108, or the internal sealing element. Internal crack detection device 216I can detect cracks which have propagated from the edge 110 of chip 100 through the sealing element(s) and may reach circuit region 105.

As shown in FIG. 2B, sealing structure 107 may further comprise an external crack detection device 216E arranged in interconnection structure 102 around sealing element 108.

As a variant, one or the other of crack detection devices 216I and 216E may be omitted. Further, sealing element 108 may be omitted.

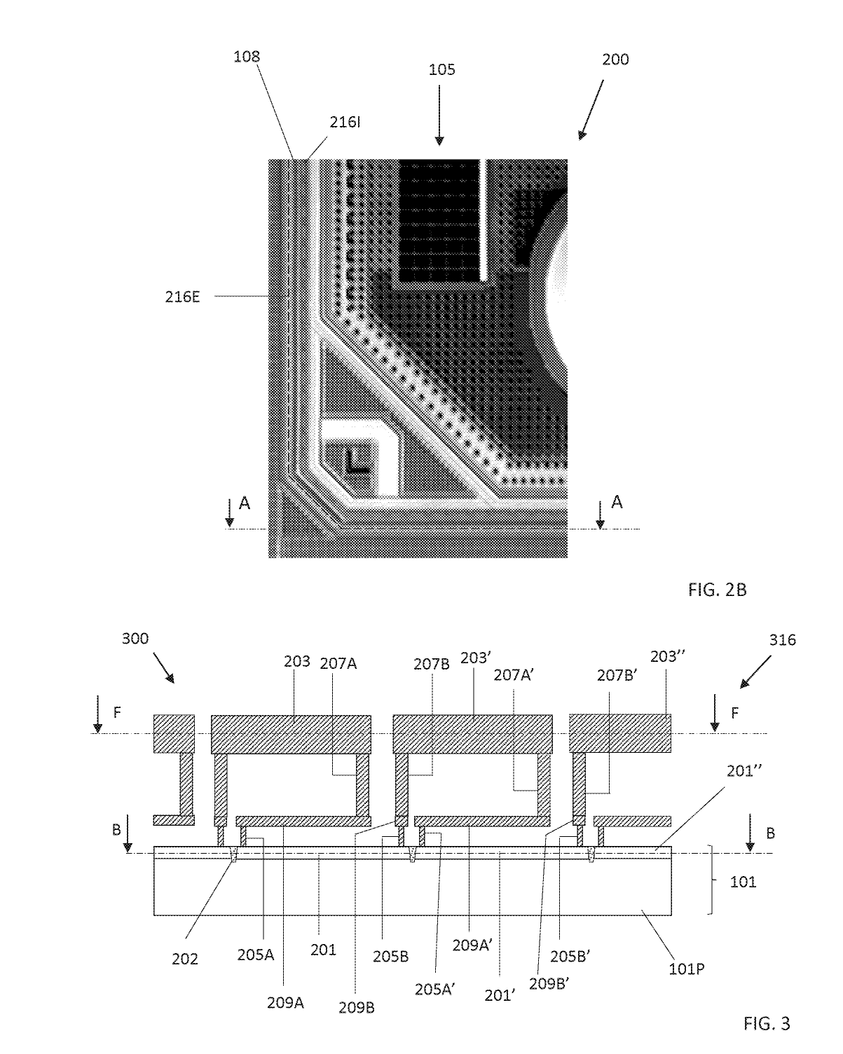

FIG. 3 is a cross-sectional view, partial and simplified, of an example of an electronic chip 300 according to another embodiment.

Electronic chip 300 comprises, for example, the same elements as the chip 200 shown in FIGS. 2A and 2B. Chip 300 further comprises a crack detection device 316 similar to crack detection device 216, with the difference that the structure, formed by vias 205A, 205B, 207A, and 207B, the lower strip 201, the upper strips 203 and 203', and tracks 209A and 209', is not symmetrical.

In this embodiment, vias 205B and 207B are aligned.

In this embodiment, each via 207B is located vertically in line with a via 205B. In this embodiment, each of vias 205B and 207B is located vertically in line with the second end of the underlying lower conductive strip 201. Further, in this embodiment, each of vias 205B and 207B is located vertically in line with the first end of the overlying upper conductive strip 203'.

As an example, the third conductive via 207A is located vertically in line with an intermediate portion located in the vicinity of the second end of the underlying lower conductive strip 201, the intermediate portion being located between the second end and the central portion of the lower conductive strip 201.

As an example, the first conductive via 205A is located vertically in line with an intermediate portion located in the vicinity of a second end of the overlying upper conductive strip 203, the intermediate portion being located between the second end and the central portion of the upper conductive strip 203.

More generally, conductive tracks 201 and 203 may have other arrangements than those described in relation with FIGS. 2A and 3. According to an aspect of the described embodiments, at least 80%, preferably at least 90%, of the length of the crack detection device is occupied, in top view or in a horizontal cross-sectional plane FF in the upper metallization level of conductive tracks 203, 203', 203'', by the upper conductive tracks 203, 203', 203''.

Similarly, according to an aspect of the described embodiments, at least 80%, preferably at least 90%, of the length of the crack detection device is occupied, in top view, or in a horizontal cross-section plane BB in the level of lower conductive strips 201, 201', 201'', by the lower conductive strips 201, 201', 201''.

An advantage of the described embodiments is linked to the shape of the serpentine forming the conductive path of crack detection device 216, comprising a succession of nested head-to-tail loops, providing a good coverage of the detection surface by both the upper conductive strips 203 and the lower conductive strips 201. This enables to increase the detection sensitivity.

The short distance separating consecutive lower conductive strips 201 and the short distance separating consecutive upper conductive strips 203 also enables to increase the detection sensitivity.

Another advantage of the described embodiments is that the presence of the intermediate conductive tracks enables to detect intermetallic delaminations.

Another advantage of the described embodiments is linked to the use of a semiconductor material, non-ductile (that is, a material that cannot be elongated, stretched, or extended without breaking) or less ductile than the metals of the interconnection structure, to form the lower conductive strips 201. This allows a better detection of vertical cracks or delaminations between the metallization levels and the semiconductor substrate.

Various embodiments and variants have been described. Those skilled in the art will understand that certain features of these various embodiments and variants may be combined, and other variants will occur to those skilled in the art. In particular, although this has not been shown in FIGS. 2A and 2B, it can be provided for each conductive via 205A, 205B, 207A, and 207B to correspond to a set of a plurality of grouped conductive vias, that is, conductive vias formed close to one another.

In any case, the contact surfaces between conductive vias, 205A, 207A, 207B and conductive strips 201, 203 are preferably entirely within 25%, for example 20%, for example 10%, of the length of the conductive strips closest to the ends of the conductive strips. That is, preferably, no electrical connection via is in contact with the upper surface of conductive strips 201 in a central part extending over 60%, preferably 80%, of the length of each strip, and no electrical connection via is in contact with the underside of conductive strips 203 in a central part extending over 60%, preferably 80%, of the length of each strip.

In other words, the connection surfaces of the conductive strips 201 and 203 are preferably located entirely within the 25%, for example within the 20%, for example within the 10%, of the length of the conductive strips closest to the ends of the conductive strips. More specifically, the connection surfaces of each lower conductive strip 201 to the two upper conductive strips 203 above it, i.e., the surfaces by which the lower conductive strip 201 is connected respectively to the two upper conductive strips 203 above it, are preferably located entirely within the 25%, for example within the 20%, for example within the 10%, of the length of the lower conductive strip 201 closest to the two ends of said strip. Similarly, the connection areas of each upper conductive strip 203 to the two underlying lower conductive strips 201, i.e., the areas through which the upper conductive strip 203 is connected respectively to the underlying lower conductive strips 201, are preferably located entirely within the 25%, for example within the 20%, for example within the 10%, of the length of the upper conductive strip 203 closest to the two ends of said strip.

Finally, the practical implementation of the described embodiments and variants is within the abilities of those skilled in the art based on the functional indications given hereabove.

1. A crack detection device, comprising:
alternating lower conductive strips and upper conductive strips connected in series,
wherein connection surfaces of the conductive strips to each other are entirely located within 25% of a length of the conductive strips closest to the ends of the conductive strips.

2. The device according to claim 1, wherein the connection surfaces of the conductive strips to each other are entirely located within the 20% of the length of the conductive strips closest to the ends of the conductive strips.

3. The device according to claim 1, wherein at least 80% of a length of the device is occupied, as viewed from above, by the upper conductive strips and at least 80% of the length of the device is occupied, when viewed from below, by the lower conductive strips.

4. The device according to claim 1, wherein the lower conductive strips are made of a doped semiconductor material and the upper conductive strips are made of metal.

5. The device according to claim 1, wherein the lower conductive strips and upper conductive strips define a conductive path between first electrical connection terminal and a second electrical connection terminal, respectively. of the device.

6. The device according to claim 5, wherein the conductive path comprises, for each lower conductive strip:
a first conductive via on top of and in contact with the lower conductive strip;
a second conductive via on top of and in contact with the lower conductive strip;
a third conductive via under and in contact with an overlying upper conductive strip;
a fourth conductive via under and in contact with another overlying upper conductive strip;
at least one first intermediate conductive track connecting the first and third conductive vias; and
at least one second intermediate conductive track connecting the second and fourth conductive vias;
wherein the first conductive via is located vertically in line with a first end of the lower conductive strip and the second conductive via is located in line with a second end of the lower conductive strip; and
wherein the third conductive via is located vertically in line with one end of the overlying upper conductive strip and the fourth conductive via is located vertically in line with one end of the other overlying upper conductive strip.

7. The device according to claim 6, wherein:
the first conductive via is located vertically in line with a central portion of the overlying upper conductive strip;
the second conductive via is located vertically in line with a central portion of the other overlying upper conductive strip;
the third conductive via is located vertically in line with a central portion of the lower conductive strip; and
the fourth conductive via is located vertically in line with said central portion of the lower conductive strip.

8. The device according to claim 7, wherein, for each lower conductive strip, said central portion of the lower conductive strip occupies less than 50% of the length of said lower conductive strip.

9. The device according to claim 6, wherein:
the fourth conductive via is aligned with the second conductive via;
the fourth conductive via is located vertically in line with said second end of the lower conductive layer; and
the second conductive via is located vertically in line with said end of the other overlying upper conductive strip.

10. The device according to claim 9, wherein the third conductive via is located vertically in line with an intermediate portion of the lower conductive strip located in the vicinity of the second end of the lower conductive strip, said intermediate portion being located between a central portion and the second end of the lower conductive strip.

11. The device according to claim 6, wherein, for each lower conductive strip, the first via is entirely located vertically in line with the 25% of the length of the strip most distant from the second end of said lower conductive strip, and the second via is entirely located vertically in line with the 25% of the length of the lower conductive strip most distant from the first end of said lower conductive strip.

12. The device according to claim 1, wherein the lower conductive strips are made of silicon.

13. The device according to claim 1, formed in and on a semiconductor substrate, wherein the semiconductor substrate comprises a doped portion of a first type of conductivity, the lower conductive strips being entirely formed in the doped portion of the semiconductor substrate.

14. The device according to claim 1, wherein the lower conductive strips are separated two by two by insulating trenches.

15. The device according to claim 1, wherein each lower conductive strip is separated from a neighboring lower conductive strip by a distance in a range from 5 nm to 10 µm.

16. The device according to claim 1, wherein each upper conductive strip is separated from a neighboring upper conductive strip by a distance in a range from 20 nm to 10 µm.

17. An electronic chip comprising the crack detection device according to claim 1, wherein the electronic chip is bounded by an edge, and the crack detection device is disposed between the edge of the electronic chip and an electronic circuit region of the electronic chip.

18. An electronic chip, comprising:
a semiconductor substrate; and
a crack detection device formed inside and on top of the semiconductor substrate or on top of the semiconductor substrate;
the crack detection device comprising, between first and second electrical connection terminals of the device, a serpentine conductive path comprising an alternation of lower conductive strips and of upper conductive strips connected in series;
wherein the serpentine conductive path comprises, for each lower conductive strip:
a first conductive via on top of and in contact with the lower conductive strip;
a second conductive via on top of and in contact with the lower conductive strip;
a third conductive via under and in contact with an overlying upper conductive strip;
a fourth conductive via under and in contact with another overlying upper conductive strip;
at least one first intermediate conductive track connecting the first and third conductive vias; and
at least one second intermediate conductive track connecting the second and fourth conductive vias;
wherein the first conductive via is located vertically in line with a first end of the lower conductive strip and the second conductive via is located in line with a second end of the lower conductive strip;
wherein the third conductive via is located vertically in line with one end of the overlying upper conductive strip and the fourth conductive via is located vertically in line with one end of the other overlying upper conductive strip;
wherein at least 80% of the length of the crack detection device is occupied, in top view, by the upper conductive strips and at least 80% of the length of the crack detection device being occupied, in bottom view, by the lower conductive strips; and
wherein the lower conductive strips are made of a doped semiconductor material and the upper conductive strips are made of metal.

19. The electronic chip according to claim 18, wherein the conductive vias in contact with the lower conductive strips are located entirely opposite the 25% of the length of the lower conductive strips closest to each end, and wherein the conductive vias in contact with the upper conductive strips are wholly located opposite 25% of the length of the upper conductive strips closest to each end.

20. The electronic chip according to claim 18, wherein, for each lower conductive strip, the first via is entirely located vertically in line with the 25% of the length of the strip most distant from the second end of said lower conductive strip, and the second via is entirely located vertically in line with the 25% of the length of the lower conductive strip most distant from the first end of said lower conductive strip.
